(19) United States
(12) Patent Application Publication
(10) Pub. No.: US 2026/0064015 A1
(43) Pub. Date: Mar. 5, 2026

(54) METHOD FOR CORRECTING OVERLAY AND METHOD FOR FABRICATING SEMICONDUCTOR DEVICE COMPRISING THE SAME

(71) Applicant: Samsung Electronics Co., Ltd., Suwon-si (KR)

(72) Inventors: Hyeonjun Ha, Suwon-si (KR); Jaeil Lee, Suwon-si (KR)

(21) Appl. No.: 19/063,115

(22) Filed: Feb. 25, 2025

(30) Foreign Application Priority Data
Aug. 27, 2024 (KR) 10-2024-0115164

(51) Int. Cl. G03F 7/00

(52) U.S. Cl. CPC G03F 7/70633; G03F 7/70725

(57) ABSTRACT

A semiconductor manufacturing method with overlay correction includes measuring an overlay between a lower pattern and an upper pattern, wherein the lower pattern is formed using a first exposure apparatus and the upper pattern is formed using a second exposure apparatus operating with an exposure method that is different from an exposure method of the first exposure apparatus, correcting, among components of the overlay, a first overlay parameter by correcting a second overlay parameter that has a crosstalk relationship with the first overlay parameter, the second overlay parameter being corrected via physical actuation of the first exposure apparatus and the second exposure apparatus, and using the corrected first overlay parameter to manufacture a semiconductor device.

### CROSS-REFERENCE TO RELATED APPLICATION

This application is based on and claims priority under 35 U.S.C. § 119 to Korean Patent Application No. 10-2024-0115164, filed on Aug. 27, 2024, in the Korean Intellectual Property Office, the disclosure of which is incorporated by reference herein in its entirety.

### BACKGROUND

The inventive concept relates to an overlay correction method and a method of manufacturing a semiconductor device, and more particularly, to an overlay correction method and a method of manufacturing a semiconductor device in an environment in which both a Deep Ultraviolet (DUV) device and an Extreme Ultraviolet (EUV) device are used.

With the recent trend towards scaling down of line widths in semiconductor circuits, layers using EUV devices are increasing. For example, multilayered patterns are formed by combining the DUV device with the EUV device within a single chip. Overlay generally resulting from the combination of the DUV device and the EUV device is sometimes called Cross Matched Machine Overlay (xMMO).

Besides the difference that the DUV device and the EUV device use light sources with different wavelengths, there can be significant differences in terms of wafer stages, reticles, slits, optical systems, and the like. Because of such differences between the DUV device and the EUV device, overlay misalignment issues arise while fine patterns are formed. Such overlay misalignment issues can potentially pose challenges for overlay control, for example if electronic components formed by separate patterns fail to align correctly.

### SUMMARY

Aspects of the inventive concept provide an overlay correction method and a method of manufacturing a semiconductor device by using the overlay correction method in an environment in which both a Deep Ultraviolet (DUV) device and an Extreme Ultraviolet (EUV) device are used.

Technical problems to be solved by the inventive concept are not limited to the above description, and other technical problems may be clearly understood by one of ordinary skill in the art from the descriptions provided hereinafter.

According to an aspect of the inventive concept, there is provided a semiconductor manufacturing method with overlay correction including measuring an overlay between a lower pattern and an upper pattern, wherein the lower pattern is formed using a first exposure apparatus and the upper pattern is formed using a second exposure apparatus operating with an exposure method that is different from an exposure method of the first exposure apparatus, correcting, among components of the overlay, a first overlay parameter by correcting a second overlay parameter that has a crosstalk relationship with the first overlay parameter, the second overlay parameter being corrected via physical actuation of the first exposure apparatus and the second exposure apparatus, and using the corrected first overlay parameter to manufacture a semiconductor device.

According to another aspect of the inventive concept, there is provided a semiconductor manufacturing method with overlay correction including measuring an overlay between a lower pattern formed using a first exposure apparatus and an upper pattern formed using a second exposure apparatus, obtaining a measured value of a first overlay parameter among overlay parameters of the overlay, obtaining a first correction value of the first overlay parameter, obtaining a second correction value of a second overlay parameter from the first correction value of the first overlay parameter, transmitting the second correction value of the second overlay parameter to the first exposure apparatus and the second exposure apparatus, wherein an exposure method of the first exposure apparatus is different from an exposure method of the second exposure apparatus, and wherein the first overlay parameter has a crosstalk relationship with the second overlay parameter, and using the second correction value of the second overlay parameter to manufacture a semiconductor device.

According to another aspect of the inventive concept, there is provided a method of manufacturing a semiconductor device by using a first exposure apparatus and a second exposure apparatus which use different exposure methods, the method including forming a lower pattern on a first semiconductor substrate by using the first exposure apparatus, forming an upper pattern on the lower pattern by using the second exposure apparatus, measuring an overlay between the lower pattern and the upper pattern, obtaining a measured value of a first overlay parameter among overlay parameters of the overlay, obtaining a first correction value of the first overlay parameter, obtaining a second correction value of a second overlay parameter having a crosstalk relationship with the first overlay parameter, from the first correction value of the first overlay parameter, transmitting the second correction value of the second overlay parameter to the first exposure apparatus and the second exposure apparatus, performing an exposure process on a second semiconductor substrate by using the first exposure apparatus and the second exposure apparatus according to the transmitted second correction value of the second overlay parameter, performing patterning on the second semiconductor substrate, and performing a subsequent semiconductor process on the second semiconductor substrate, wherein, in the performing of the exposure process, the second overlay parameter is corrected by operating a lens of the first exposure apparatus according to the transmitted second correction value of the second overlay parameter, the second overlay parameter is corrected by tilting a reticle stage of the second exposure apparatus around a scan direction of the reticle stage according to the transmitted second correction value of the second overlay parameter, and the first overlay parameter is corrected by an amount depending on a crosstalk ratio in the second correction value of the second overlay parameter in the second exposure apparatus.

### BRIEF DESCRIPTION OF THE DRAWINGS

Embodiments will be more clearly understood from the following detailed description taken in conjunction with the accompanying drawings in which:

FIG. 1 illustrates a schematic structure of a first exposure apparatus used in a method of manufacturing a semiconductor device, according to embodiments;

FIG. 2 illustrates a detailed structure of a controller of the first exposure apparatus of FIG. 1;

FIG. 3 illustrates a schematic structure of a second exposure apparatus used in a method of manufacturing a semiconductor device, according to embodiments;

FIG. 4 illustrates a detailed structure of a controller of the second exposure apparatus of FIG. 3;

FIG. 5 illustrates a schematic structure of a main alignment controller used in a method of manufacturing a semiconductor device, according to embodiments;

FIGS. 6A and 6B are cross-sectional views showing overlay errors;

FIG. 7 is a graph showing measurement results of overlay between an upper pattern and a lower pattern;

FIG. 8 is a schematic flowchart of an overlay correction method according to embodiments;

FIG. 9 is a flowchart schematically showing an example of an operation of correcting a first overlay parameter by using a second overlay parameter of FIG. 8;

FIG. 10 is a schematic flowchart of an overlay correction method according to other embodiments; and

FIG. 11 is a schematic flowchart of a method of manufacturing a semiconductor device, according to embodiments.

### DETAILED DESCRIPTION OF THE EMBODIMENTS

Hereinafter, one or more embodiments are described in detail with reference to the attached drawings. Like reference numerals in the drawings denote like elements, and repeated descriptions thereof will be omitted.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

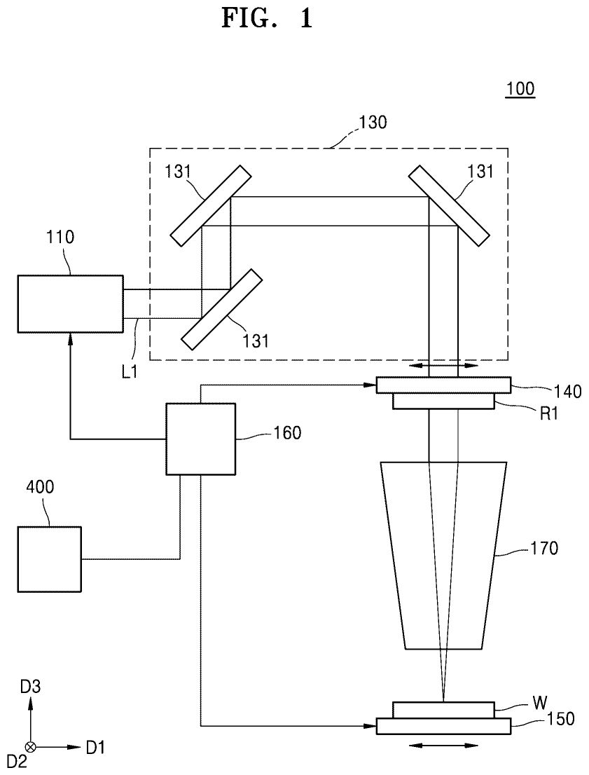

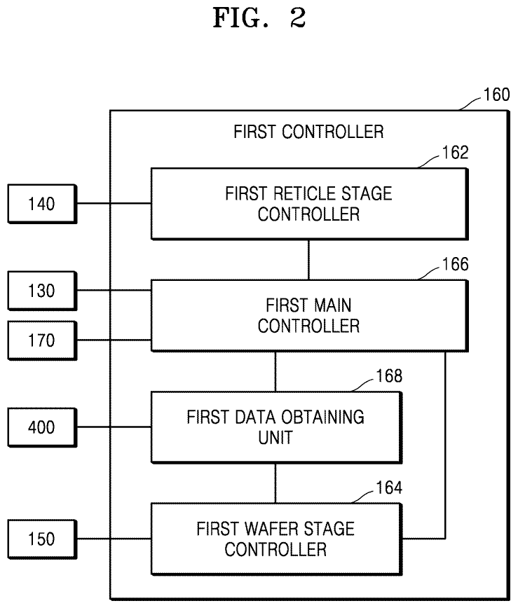

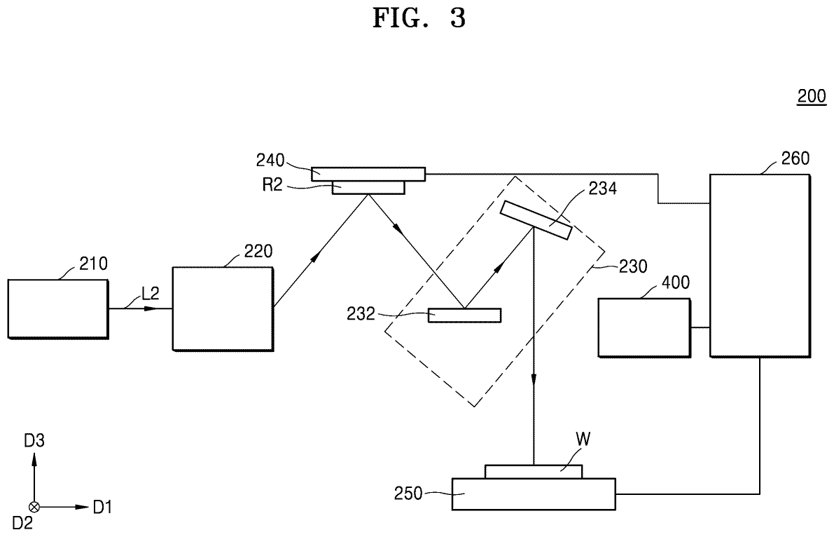

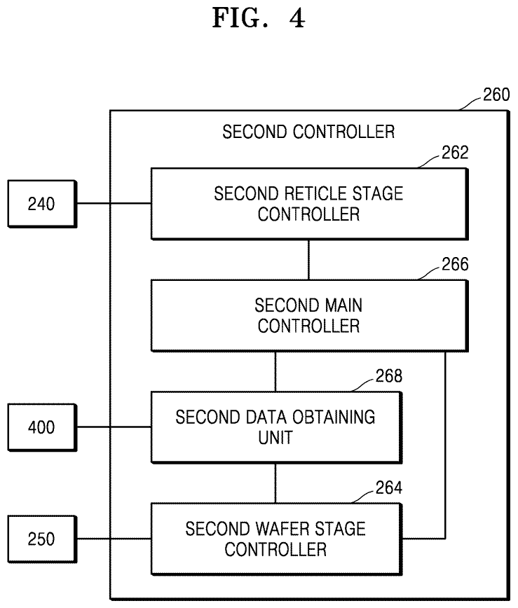

FIG. 1 illustrates a schematic structure of a first exposure apparatus 100 used in a method of manufacturing a semiconductor device (e.g., one or more transistor, or one or more integrated circuit formed as a semiconductor chip or chips), according to embodiments, and FIG. 2 illustrates a detailed structure of a controller of the first exposure apparatus of FIG. 1. In some embodiments, the disclosed semiconductor manufacturing process may involve forming a lower pattern with the first exposure apparatus 100 as well as an upper pattern with a second exposure apparatus 200, as described in the examples of FIGS. 3 and 4 below. As disclosed herein, the second exposure apparatus 200 can operate with an exposure method (e.g., Extreme Ultraviolet (EUV)) that is different from an exposure method (e.g., Deep Ultraviolet (DUV) and/or near ultraviolet (UV)) of the first exposure apparatus 100.

Referring to FIG. 1, the first exposure apparatus 100 may include a first light source unit 110, a first optical system 130, a second optical system 170, and a first controller 160. Each of the controllers disclosed herein may be a processor (i.e., a hardware circuit), such as a microprocessor, a CPU (Central Processing Unit), a GPU (graphics processor), a digital signal processor (DSP), a field-programmable gate array (FPGA), etc., and may be part of a computer. Such a controller may be formed by several interconnected controllers and may be configured by software.

The first light source unit 110 may include, for example, a laser light source with a center wavelength ranging from about 150 nm to about 500 nm. The first light source unit 110 may include a Deep Ultraviolet (DUV) light source, for example, a near ultraviolet (UV) light source such as a G-line laser or an I-line laser or an excimer laser light source such as a KrF laser, ArF laser, or F₂ laser. For example, the first light source unit 110 may include an ArF laser light source with a center wavelength of about 193 nm.

The first optical system 130 may transmit first light L1 generated by the first light source unit 110 to a first reticle R1. The first optical system 130 may include a plurality of optical devices 131 configured to guide the first light L1 to the first reticle R1, and the optical devices 131 may each be a lens or a mirror.

The first reticle R1 may be provided on a first reticle stage 140. The first reticle R1 may be, for example, a transmissive mask. Although not shown, the first reticle R1 may be fixed to the first reticle stage 140 by, for example, three clamps, and the clamps may be located at the edge of the first reticle R1. The first reticle stage 140 may include a material through which the first light L1 generated from the first light source unit 110 may pass.

The first reticle stage 140 may move in a D2 direction (an x direction) and a D1 direction (a y direction) on a D2-D1 plane (an x-y plane) and may move in a D3 direction (a z direction) that is perpendicular to the D2-D1 plane (the x-y plane). In addition, the first reticle stage 140 may rotate on the D2-D1 plane (the x-y plane) around a D3 axis (the z axis) or rotate on a D1-D3 plane (a y-z plane) or a D2-D3 plane (an x-z plane) around any one axis on the D2-D1 plane (the x-y plane), for example, the D3 direction (the z axis) or D1 direction (the y axis). Due to the movement of the first reticle stage 140, the first reticle R1 may move in the D2 direction (the x direction), D1 direction (the y direction), or D3 direction (the z direction) and may also rotate around the D2 direction (the x direction), D1 direction (the y direction), or D3 direction (the z direction).

The second optical system 170 may focus the first light L1, which passes through the first reticle stage 140 and the first reticle R1, onto one point on the wafer W. The second optical system 170 may include, for example, a plurality of condenser lenses. The condenser lenses of the second optical system 170 may condense the first light L1 having passed through the first reticle R1 by a specific magnification (e.g., 4 times, 6 times, or 8 times) and project the condensed first light L1 onto the wafer W.

The wafer W may be provided on the first wafer stage 150. The wafer W may be a wafer with which an integrated circuit is to be formed, and may include a base semiconductor substrate (i.e., an initial substrate) including at least one of silicon, germanium, or silicon-germanium. An upper surface of the wafer W may be coated with a photoresist material reacting with the first light L1.

Photoresist patterns may be formed by developing the photoresist material, for example by exposure to the first light L1. Mask layers under the photoresist patterns may be patterned by using the photoresist patterns as etch masks, and thus, mask patterns may be formed on the wafer W. Target layers under the mask patterns may be patterned by using the mask patterns as etch masks, and target patterns may be formed on the wafer W.

The first controller 160 may be electrically connected to the first light source unit 110, the first optical system 130, the first reticle stage 140, the second optical system 170, and the first wafer stage 150, and may control the same. For example, the first controller 160 may control a driving motor connected to each of the first optical system 130, the first reticle stage 140, the second optical system 170, and the first wafer stage 150. The first optical system 130 and the second optical system 170 may be moved by the driving motors in the first direction D1, the second direction D2, and/or the third direction D3. The first reticle stage 140 and the first wafer stage 150 may be moved by the driving motors in the first direction D1 or the second direction D2.

The first direction D1 may be one direction parallel to the upper surface of the first reticle R1, and the second direction D2 may be another direction that is parallel to the upper surface of the first reticle R1 and intersects the first direction D1. The third direction D3 may be orthogonal to the first direction D1 and the second direction D2. For example, the first direction D1 may be orthogonal to the second direction D2. For example, the first direction D1 may be a scan direction in which a slit moves (e.g., D1 may be a direction along which an exposure target varies over time during scanning), and the second direction D2 may be a direction in which a slit extends, wherein the slit defines a region that is an exposure target. In addition, the first reticle stage 140 and the first wafer stage 150 may be rotated by the driving motor in a clockwise direction or a counterclockwise direction.

Referring to FIG. 2, the first controller 160 may include, for example, a first reticle stage controller 162, a first wafer stage controller 164, a first main controller 166, and a first data obtaining unit 168.

The first reticle stage controller 162 may control the movement of the first reticle stage 140. Here, the movement of the first reticle stage 140 may include movement in the first direction D1, the second direction D2, or the third direction D3 and rotation around the first direction D1, the second direction D2, or the third direction D3.

The first wafer stage controller 164 may control the movement of the first wafer stage 150. The movement of the first wafer stage 150 may include movement in the first direction D1, the second direction D2, or the third direction D3 and rotation around the first direction D1, the second direction D2, or the third direction D3.

The first main controller 166 may generally control the first reticle stage controller 162 and the first wafer stage controller 164. For example, the first main controller 166 may control the first reticle stage controller 162 and the first wafer stage controller 164 to synchronize the first reticle stage 140 with the first wafer stage 150 along the scan direction during the exposure process.

In addition, although not shown in FIG. 2, the first main controller 166 may further include various control components during the exposure process. For example, the first main controller 166 may include a focus controller, a data storage, an exposure processor, and the like.

The focus controller obtains a focus correction value by comparing a measured focus offset with a required focus offset and transmits the focus correction value to the first wafer stage controller 164 to enable the first wafer stage controller 164 to control the movement of the first wafer stage 150 in the direction D3, and the like.

The data storage may store data regarding a correction value of a second overlay parameter (e.g., of a plurality of overlay parameters) that is transmitted from a main alignment controller 400, data regarding the focus correction value obtained by the focus controller, or the like. After the movement of the first wafer stage 150 is controlled through the focus controller, the exposure processor may perform the exposure process while synchronizing the first reticle stage 140 with the first wafer stage 150 along the scan direction (e.g., the direction D1) through the first main controller 166.

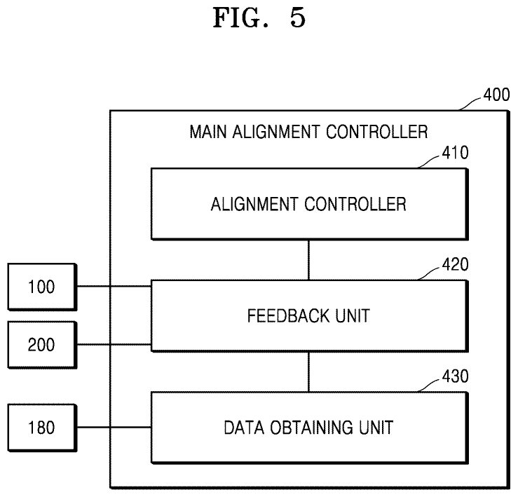

The first data obtaining unit 168 may receive feedback on the correction value of the second overlay parameter from the main alignment controller 400 and may transmit the feedback to the first main controller 166. For example, an overlay error regarding patterns on the wafer may be measured by a measuring device 180 (e.g., see FIG. 5), and data regarding the overlay error may be transmitted to the main alignment controller 400. In various examples, the measuring device 180 may be a microscope, such as an optical microscope or an electron microscope, and may be implemented as a separate device or included in the first exposure apparatus 100 (although not shown in FIG. 1), as described below. In addition, the correction value of the second overlay parameter that is obtained by the main alignment controller 400 may be transmitted to the first data obtaining unit 168. As a result, the first data obtaining unit 168 may obtain data regarding overlay parameters from the main alignment controller 400 and transmit the data to the first main controller 166. For example, in the first exposure apparatus 100, the first data obtaining unit 168 may obtain data regarding the second overlay parameter, for example, an RK7 parameter, through the main alignment controller 400 and transmit the data to the first main controller 166. The data regarding the overlay parameters obtained by the first data obtaining unit 168 is not limited to the data regarding the RK7 parameter, which is described below.

FIG. 3 illustrates a schematic structure of a second exposure apparatus 200 used in a method of manufacturing a semiconductor device, according to embodiments, and FIG. 4 illustrates a detailed structure of a controller of the second exposure apparatus of FIG. 3. In some examples, the second exposure apparatus 200 can operate with an exposure method (e.g., Extreme Ultraviolet (EUV)) that is different from an exposure method (e.g., Deep Ultraviolet (DUV) and/or near ultraviolet (UV)) of the first exposure apparatus 100. For example, multilayered patterns may be formed by combining the device formed using second exposure apparatus 200 with the device formed using first exposure apparatus 100 within a single chip, for example resulting in an overlay such as a Cross Matched Machine Overlay (xMMO).

Referring to FIGS. 3 and 4, a second exposure apparatus 200 according to the present embodiment may include a second light source unit 210, a third optical system 220 (e.g., referred to as the 1st Optics of second exposure apparatus 200), a fourth optical system 230 (e.g., 2nd Optics), a second reticle stage 240, a second wafer stage 250, and a second controller 260.

The second light source unit 210 may generate second light L2 with high energy density within a wavelength range of about 5 nm to about 50 nm, and may emit the second light L2. The second light L2 may be Extreme Ultraviolet (EUV) light. For example, the second light source unit 210 may generate the second light L2 with high energy density in a wavelength of about 13.5 nm, thus outputting the second light L2. The second light source unit 210 may be a plasma-based light source or a synchrotron radiation light source. Here, the plasma-based light source may refer to a light source that generates plasma and uses light emitted by the plasma and may include a Laser-Produced Plasma (LPP) light source, a Discharge-Produced Plasma (DPP) light source, or the like.

The second light source unit 210 may be, for example, a plasma-based light source. The second light source unit 210 is not limited to the plasma-based light source. To increase the energy density of the illumination light that enters the third optical system 220, the plasma-based light source may include a condenser mirror, such as an oval mirror and/or a spherical mirror, which focuses the second light L2.

The third optical system 220 may include a plurality of mirrors. For example, the third optical system 220 may include two or three mirrors. However, the number of mirrors included in the third optical system 220 is not limited to two or three. The third optical system 220 may transmit the second light L2 from the second light source unit 210 to the second reticle R2. For example, the second light L2 from the second light source unit 210 may be incident to the second reticle R2 arranged on the second reticle stage 240 through reflection from the mirrors included in the third optical system 220. The third optical system 220 may change the second light L2, for example by making use of curved slits (e.g., curved exposure targets) to direct the second light L2 into the second reticle R2.

The second reticle R2 may be a reflective mask that includes a reflection area and a non-reflection area and/or an intermediate reflection area. The second reticle R2 may include a reflective multilayer film for reflecting EUV light and an absorption layer pattern formed on the reflective multilayer film, wherein the reflective multilayer film and the absorption layer pattern are placed on a substrate that includes a Low Thermal Expansion Coefficient Material (LTEM) such as quartz. The reflective multilayer film may have a structure in which, for example, a molybdenum (Mo) layer and a silicon (Si) layer are alternately stacked several hundred times. The absorption layer may include, for example, TaN, TaNO, TaBO, Ni, Au, Ag, C, Te, Pt, Pd, or Cr. However, the materials of the reflective multilayer film and the absorption layer are not limited to those stated above. Here, the absorption layer may correspond to the non-reflection area and/or intermediate reflection area mentioned above.

The second reticle R2 reflects the second light L2 entering through the third optical system 220 and directs the same into the fourth optical system 230. For example, the second reticle R2 may reflect the second light L2 from the third optical system 220 and structuralize the second light L2 according to a pattern formed by the reflective multilayer film and the absorption layer on the substrate, thus allowing the second light L2 to enter the fourth optical system 230. The second light L2 may be structuralized by including at least second-order diffracted light based on the pattern on the second reticle R2. The structuralized second light L2 may be incident to the fourth optical system 203 while retaining information regarding the pattern on the second reticle R2. The structuralized second light L2 may be projected onto the wafer W, enabling the formation of an image corresponding to the pattern after passing through the fourth optical system 230. Here, the wafer W may be a semiconductor wafer or a compound semiconductor wafer that includes at least one of Si, Ge, or Si—Ge.

The fourth optical system 230 may include a plurality of mirrors. FIG. 3 shows that the fourth optical system 230 includes two mirrors, that is, a first mirror 232 and a second mirror 234, but it is only an example, and the present disclosure is not limited thereto. The fourth optical system 230 may include more mirrors. For example, in the second exposure apparatus 200 according to the present embodiment, the fourth optical system 230 may include four to eight mirrors. However, the number of mirrors included in the fourth optical system 230 is not limited to four to eight.

As described above, the fourth optical system 230 may transmit the second light L2, reflected from the second reticle R2, to the wafer W through reflections from mirrors.

The second reticle R2 may be arranged on the second reticle stage 240. The second reticle stage 240 may move on the D2-D1 plane (the x-y plane) in the D2 direction (the x direction) and the D1 direction (the y direction) and may move in the D3 direction (the z direction) that is perpendicular to the D2-D1 plane (the x-y plane). In addition, the second reticle stage 240 may rotate on the D2-D1 plane (the x-y plane) around the D3 axis (the z axis) or rotate on the D1-D3 plane (the y-z plane) or the D2-D3 plane (the x-z plane) around any one axis on the D2-D1 plane (the x-y plane), for example, the D3 direction (the z axis) or the D1 direction (the y axis). Due to the movement of the second reticle stage 240, the second reticle R2 may move in the D2 direction (the x direction), the D1 direction (the y direction), or the D3 direction (the z direction) and may also rotate around the D2 direction (the x direction), the D1 direction (the y direction), or the D3 direction (the z direction).

The wafer W may be arranged on the second wafer stage 250. The second wafer stage 250 may move on the D2-D1 plane (the x-y plane) in the D2 direction (the x direction) and the D1 direction (the y direction) and may move in the D3 direction (the z direction) that is perpendicular to the D2-D1 plane (the x-y plane). In addition, the second wafer stage 250 may rotate on the D2-D1 plane (the x-y plane) around the D3 axis (the z axis) or rotate on the D1-D3 plane (the y-z plane) or the D2-D3 plane (the x-z plane) around any one axis on the D2-D1 plane (the x-y plane), for example, the D3 direction (the z axis) or the D1 direction (the y axis). Due to the movement of the second wafer stage 250, the second reticle R2 may move in the D2 direction (the x direction), the D1 direction (the y direction), or the D3 direction (the z direction) and may also rotate around the D2 direction (the x direction), the D1 direction (the y direction), or the D3 direction (the z direction).

The second controller 260 may control the second reticle stage 240 and the second wafer stage 250.

For example, the second controller 260 may control a driving motor coupled to each of the second reticle stage 240 and the second wafer stage 250. The second reticle stage 240 and the second wafer stage 250 may be moved by the driving motors in the first direction D1 or the second direction D2.

The first direction D1 may be one direction parallel to the upper surface of the second reticle R2, and the second direction D2 may be another direction that is parallel to the upper surface of the second reticle R2 and intersects the first direction D1. For example, the first direction D1 may be orthogonal to the second direction D2. For example, the first direction D1 may be a scan direction in which a slit moves, and the second direction D2 may be a direction in which a slit extends, wherein the slit defines a region that is an exposure target. In addition, the second reticle stage 240 and the second wafer stage 280 may be rotated by the driving motors in a clockwise direction or a counterclockwise direction.

Referring to FIG. 4, the second controller 260 may include, for example, a second reticle stage controller 262, a second wafer stage controller 264, a second main controller 266, and a second data obtaining unit 268.

The second reticle stage controller 262 may control the movement of the second reticle stage 240. Here, the movement of the second reticle stage 240 may include movement in the first direction D1, the second direction D2, or the third direction D3 and rotation around the first direction D1, the second direction D2, or the third direction D3.

The second wafer stage controller 264 may control the movement of the second wafer stage 250. The movement of the second wafer stage 250 may include movement in the first direction D1, the second direction D2, or the third direction D3 and rotation around the first direction D1, the second direction D2, or the third direction D3.

The second main controller 266 may generally control the second reticle stage controller 262 and the second wafer stage controller 264. For example, the second main controller 266 may control the second reticle stage controller 262 and the second wafer stage controller 264 to synchronize the second reticle stage 240 with the second wafer stage 250 along the scan direction during the exposure process.

In addition, although not shown in FIG. 4, the second main controller 266 may further include various control components during the exposure process. For example, the second main controller 266 may include a focus controller, a data storage, an exposure processor, and the like.

The focus controller obtains a focus correction value by comparing a measured focus offset with a required focus offset and transmits the focus correction value to the second wafer stage controller 264 to enable the second wafer stage controller 264 to control the movement of the second wafer stage 250 in the direction D3 and the like.

The data storage may store data regarding a correction value of the second overlay parameter (e.g., of a plurality of overlay parameters) that is transmitted from the main alignment controller 400, data regarding the focus correction value obtained by the focus controller, or the like. After the movement of the second wafer stage 250 is controlled through the focus controller, the exposure processor may perform the exposure process while synchronizing the second reticle stage 240 with the second wafer stage 250 along the scan direction (the direction D1) through the second main controller 266.

The second data obtaining unit 268 may receive feedback on the correction value of the second overlay parameter from the main alignment controller 400 and may transmit the feedback to the second main controller 266. For example, an overlay error regarding patterns on the wafer may be measured by the measuring device 180 (e.g., see FIG. 5), data regarding the overlay error may be transmitted to the main alignment controller 400, and the correction value of the second overlay parameter that is obtained by the main alignment controller 400 may be transmitted to the second data obtaining unit 268. In various examples, the measuring device 180 may be an optical microscope or an electron microscope, and may be implemented as a separate device or included in the second exposure apparatus 200, as described below. As a result, the second data obtaining unit 268 may obtain data regarding overlay parameters from the main alignment controller 400 and transmit the data to the second main controller 266. In the second exposure apparatus 200, the second data obtaining unit 268 may obtain data regarding the second overlay parameter, for example, an RK7 parameter, through the main alignment controller 400 and transmit the data to the second main controller 266. The data regarding the overlay parameter obtained by the second data obtaining unit 268 is not limited to the data regarding the RK7 parameter, which is described below.

FIG. 5 illustrates a schematic structure of a main alignment controller 400 used in a method of manufacturing a semiconductor device, according to embodiments. For example, the main alignment controller 400 may communicate with first controller 160 and second controller 260, as disclosed herein.

Referring to FIG. 5, the main alignment controller 400 may include an alignment controller 410, a feedback unit 420, and a data obtaining unit 430.

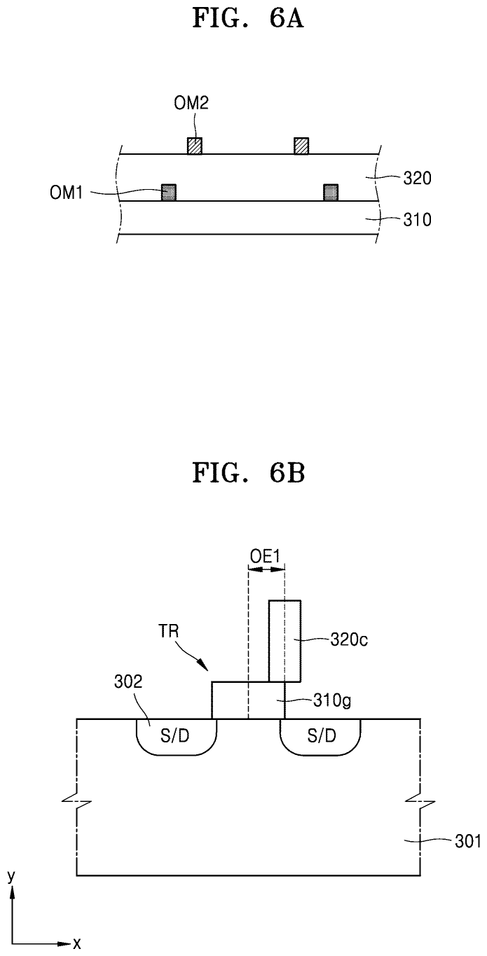

The alignment controller 410 may calculate correction values of overlay error parameters (e.g., exposure parameters). The correction values of the overlay error parameters may be calculated based on data regarding the overlay error parameters and a correlation between the overlay error parameters. Here, the overlay error parameters may refer to parameters related to (e.g., describing or characterizing) overlay errors between layers on the wafer W. Hereinafter, the overlay error parameters are simply referred to as ‘overlay parameters.’ The overlay error parameters between the layers on the wafer, that is, the overlay parameters (e.g., exposure parameters), are described in more detail in the description of FIGS. 6A and 6B.

For reference, an overlay error may refer to an overlap difference between an under layer and a current layer corresponding to an upper layer. Generally, during the exposure process of the upper layer, shots are aligned as closely as possible to the under layer, based on overlay marks on the under layer, thereby reducing overlay errors. A large overlay error, such as a significant difference in relative locations between the under layer and the current layer, may negatively affect the performance of the semiconductor device, for example if electronic components fail to align correctly.

Specifically, the alignment controller 410 may calculate the correction value of the first overlay parameter by using the measured value of the first overlay parameter transmitted from a measuring device 180 (such as an optical microscope or an electron microscope, as described below) and may derive the correction value of the second overlay parameter from the correction value of the first overlay parameter. Because the second exposure apparatus 200 uses EUV wavelengths, it may have characteristics such as non-telecentricity, curved slits, and reflective optics, which may result in crosstalk relationships among specific overlay parameters. Accordingly, the alignment controller 410 may utilize a crosstalk relationship between the first overlay parameter and the second overlay parameter to derive the correction value of the second overlay parameter from that of the first overlay parameter. The first overlay parameter may be an overlay parameter that may not be corrected through the physical actuation of the first exposure apparatus and the second exposure apparatus, and the second overlay parameter may be an overlay parameter that has a crosstalk relationship with the first overlay parameter and may be corrected through the physical actuation of the first exposure apparatus and the second exposure apparatus. In an embodiment, the first overlay parameter may be a K20 component, while the second overlay parameter may be a K7 component. K7 may indicate a second-order distortion in the x dimension, while K20 may indicate a third-order distortion in y. For example, K7 and K20 may be affected by mutual crosstalk, for instance, when a reticle y-axis tilt (image tilt Ry) occurs, K6 (e.g., rotation about the y-axis), K7, and K20 may change together. In another example, the K7 control may cause K6 and K20 fluctuations. The alignment controller 410 may calculate the correction value of the second overlay parameter by multiplying the correction value of the first overlay parameter by a crosstalk ratio.

When the first exposure apparatus 100 is a DUV device and the second exposure apparatus 200 is an EUV device, the first overlay parameter may be an RK20 parameter and the second overlay parameter may be an RK7 parameter.

In the first exposure apparatus 100 and the second exposure apparatus 200, for example, the alignment controller 410 may calculate the correction value of the second overlay parameter based on the data regarding the first overlay parameter and the correlation that is crosstalk between the first overlay parameter and the second overlay parameter. Among the overlay parameters, the first overlay parameter may be the RK20 parameter and the second overlay parameter may be the RK7 parameter.

The feedback unit 420 may provide feedback on the calculated correction values of the overlay parameters to the first exposure apparatus 100 and/or the second exposure apparatus 200. The first main controller 166 of the first exposure apparatus 100 may control the movement of the first optical system 130 and/or the second optical system 170, based on the correction values of the overlay parameters. In addition, the second reticle stage controller 262 and/or the second wafer stage controller 264 of the second exposure apparatus 200 may control the movement of the second reticle stage 240 and/or the second wafer stage 250, based on the correction values of the overlay parameters.

In more specific example, the feedback unit 420 may provide feedback on the calculated correction value of the second overlay parameter, that is, the RK7 parameter, to the first main controller 166, and the first main controller 166 may then control the lens or mirror of the first optical system 130 and/or the second optical system 170, based on the correction value of the second overlay parameter. In addition, the feedback unit 420 may provide feedback on the calculated correction value of the second overlay parameter, that is, the RK7 parameter, to the second reticle stage controller 262, and the second reticle stage controller 262 may then control the tilting of the second reticle stage 240 around the scan direction D1 of the second reticle stage 240, based on the correction value of the second overlay parameter.

According to an embodiment of the inventive concept, when both the DUV device and the EUV device are used, the second overlay parameter, that is, the RK7 parameter, may be corrected by operating the first optical system 130 and the second optical system 170 and tilting the second reticle stage 240, and the first overlay parameter, that is, the RK20 parameter, which may not be directly corrected through physical actuation of the second exposure apparatus 200, may be corrected so that the occurrence of overlay errors may be greatly reduced.

The physical actuation may refer to physical operation of a scanner, that is, an exposure apparatus, to correct overlay errors. For example, the physical actuation may include various methods involving applying pressure or tilt to a lens or mirror in the first optical system 130 and the second optical system 170, quickly moving the lens or mirror, moving a mask through the first reticle stage 140 and the second reticle stage 240 or the wafer W through the first wafer stage 150 and the second wafer stage 250, and heating the wafer W. When the overlay parameters are associated with the physical actuation of the reticle, that is, the mask, the letter R may be added to the symbol of the parameter. For example, when the K20 parameter and the K7 parameter are related to the physical actuation of the mask, the K20 parameter and the K7 parameter may be respectively referred to as the RK20 parameter and the RK7 parameter.

The measuring device 180 may measure the critical dimension (CD) or overlay errors in the patterns on the wafer. The measuring device 180 may include an optical microscope or an electron microscope such as a Scanning Electron Microscope (SEM) or a Transmission Electron Microscope (TEM). In addition, the measuring device 180 may use elliptic polarization such as Imaging Ellipsometry (IE) or Spectroscopic Imaging Ellipsometry (SIE) as a measuring method. The measuring method used by the measuring device 180 is not limited to elliptic polarization.

The measuring device 180 may be implemented as a separate device or included in the first exposure apparatus 100 and the second exposure apparatus 200. The measurement of CD or overlay errors in the patterns on the wafer by using the measuring device 180 may be during After Development Inspection (ADI) or After Cleaning Inspection (ACI).

FIGS. 6A and 6B are cross-sectional views showing overlay errors.

As described above, the disclosed semiconductor manufacturing process may include forming a lower pattern with the first exposure apparatus 100 using one exposure method (e.g., Deep Ultraviolet (DUV) and/or near ultraviolet (UV)), as well as forming an upper pattern with the second exposure apparatus 200 using a different exposure method (e.g., Extreme Ultraviolet (EUV)). In addition to the first exposure apparatus 100 and second exposure apparatus 200 using light sources with different wavelengths, there can also be significant differences, such as wafer stages, reticles, slits, optical systems, and the like. Accordingly, overlay misalignment issues can arise while fine patterns are formed, as described in the example of FIG. 6A. Such overlay misalignment issues can potentially pose challenges for overlay control, for example if electronic components formed by separate patterns fail to align correctly, as described in the example of FIG. 6B. The disclosed system and methods for overlay correction and for semiconductor device manufacturing with overlay correction can mitigate such overlay misalignment issues.

Referring to FIGS. 6A and 6B, the overlay error may be derived by measuring a first overlay mark OM1, which is formed on a first layer 310 that is a lower layer, and a second overlay mark OM2, which is formed on a second layer 320 that is an upper layer, and calculating the relative difference in positions of the first overlay mark OM1 and the second overlay mark OM2. The first overlay mark OM1 may be formed simultaneously when a pattern is formed on the first layer 310, and the second overlay mark OM2 may be formed simultaneously when a pattern is formed on the second layer 320. The overlay mark may be formed on a scribe lane of the wafer in the form of a box pattern or a bar pattern. However, the shape or position of the overlay mark is not limited thereto.

FIG. 6B shows a semiconductor device formed on a semiconductor substrate 301. For example, a transistor TR including a source/drain area 302 and a gate electrode 310g may be formed on the semiconductor substrate 301, and a vertical contact 320c connected to the gate electrode 310g may also be formed. The gate electrode 310g may correspond to the pattern formed on the first layer 310 that is the lower layer, and the vertical contact 320c may correspond to the pattern formed on the second layer 320 that is the upper layer. When there is no overlay error, the vertical contact 320c may be arranged at the center of the gate electrode 310g in the first direction (the x direction). However, as shown in FIG. 6B, the gate electrode 310g and the vertical contact 320c may have a first overlay error OE1 in the x direction because of various factors. When the first overlay error OE1 is great, the vertical contact 320c may be separate from the gate electrode 310g and connected to the source/drain area 302; alternatively, the vertical contact 320c may overlap only a portion of the gate electrode 310g and may be connected to both the gate electrode 310g and the source/drain area 302. Accordingly, the structure of the vertical contact 320c having the first overlay error OE1 may cause serious defects such as open and/or short circuit failures of the transistor TR.

For reference, the overlay may include various components. For example, the overlay may include a zero order component, a first order linear component, and nonlinear components of second order or higher, and there may be a wafer component WK or an interfield component as well as a shot component RK or an intrafield component. These components may be described by the overlay parameters.

Specifically, the zero order component may include a K1 component and a K2 component. The K1 component may be an overlay parameter generated with a uniform magnitude towards one side in the x direction, while the K2 component may be an overlay parameter generated with a uniform magnitude towards one side in the y direction. When the overlay in the x direction is defined as dx and the overlay in the y direction as dy, the K1 component may be expressed as dx=k1, while the K2 component may be expressed as dy=k2. Here, during the exposure process, the y direction may correspond to the scan direction, and the x direction may be perpendicular to the y direction. The x direction may correspond to the direction in which a slit extends. The zero order component may be included in a linear component.

The first order linear component may include a K3 component to a K6 component. The K3 component may be an overlay parameter generated with a magnitude that is proportional to the location in both directions in the x direction, and the K4 component may be an overlay parameter generated with a magnitude that is proportional to the location in both directions in the y direction. The K5 component and the K6 component may each be a component in which an overlay is vertically generated in proportion to the location. The K3 component may be expressed as dx=k3*x, while the K4 component may be expressed as dy=k4*y. In addition, the K5 component may be expressed as dx=k5*y, while the K6 component may be expressed as dy=k6*x.

The nonlinear components of second order or higher may include a K7 component to a K20 component. Additionally, the second order nonlinear component may include K7 to K12 components. The K7 component may be an overlay parameter generated with a magnitude that is proportional to the square of the location in both directions in the x direction (for example, K7 may indicate a second order distortion in x), and the K8 component may be an overlay parameter generated with a magnitude that is proportional to the square of the location in both directions in the y direction. The K9 component to the K12 component may also have overlays with magnitudes proportional to the square of the locations. The K7 component may be expressed as dx=k7*x², while the K8 component may be expressed as dy=k8*y². For example, the K7 component may indicate that pattern features have an overlay error dx (as described in FIGS. 6A-6B) that is proportional to the square x² of their position in the x direction, relative to the center of the wafer, where the constant of proportionality is k7 and the overlay error dx is also along the x direction. In addition, the K9 component may be expressed as dx=k9*x*y, the K10 component may be expressed as dy=k10*y*x, the K1l component may be expressed as dx=k11*y², and the K12 component may be expressed as dy=k12*x².

The third order nonlinear component may include a K13 component to a K20 component. The K13 component may be an overlay parameter generated with a magnitude that is proportional to the cube of the location in both directions in the x direction, while the K14 component may be an overlay parameter generated with a magnitude that is proportional to the cube of the location in both directions in the second direction (the y direction). Additionally, the K15 component to the K20 component may also have overlays generated with magnitudes proportional to the cube of the locations (for example, K20 may indicate a third order distortion in y). The K13 component may be expressed as dx=k13*x³, while the K14 component may be expressed as dy=k14*y³. In addition, the K15 component may be expressed as dx=k15*x²*y, the K16 component may be expressed as dy=k16*y²*x, the K17 component may be expressed as dx=k17*x*y², the K18 component may be expressed as dy=k18*y*x², the K19 component may be expressed as dx=k19*y³, and the K20 component may be expressed as dy=k20*x³. For example, the K20 component may indicate that pattern features have an overlay error dy (as described in FIGS. 6A-6B) that is proportional to the cube x³ of their position in the x direction, relative to the center of the wafer, where the constant of proportionality is k20 and the overlay error dy is along the y direction.

In the DUV device, all overlay parameters excluding the K20 component may be corrected through physical actuation of a projection lens, a wafer stage, or a reticle stage. Even in the EUV device, most of the overlay parameters except the K13 component and the K20 component may be corrected through the physical actuation of the wafer stage or the reticle stage, similar to the DUV device. However, unlike the DUV device, it is almost impossible to correct the K13 component and the K20 component through physical actuation in the EUV device. For example, the K13 component may be corrected through physical actuation in the DUV device but not in the EUV device. It is almost impossible to correct the K20 component through physical actuation both in the DUV device and the EUV device. For example, it may be almost impossible to correct the K20 component through physical actuation both in the DUV device and the EUV device without also correcting another overlay parameter, such as the K7 component, as disclosed herein. In another example, it may be almost impossible to determine the physical actuation needed in either the DUV device or the EUV device to correct the K20 component directly, whereas the actuation needed to correct the K7 component can be determined, thereby indirectly correcting the K20 component, as disclosed herein.

In an environment in which both the DUV device and the EUV device are used, the K20 component may not be corrected because of differences in exposure environments between the devices. For example, the DUV device may include a DUV scanner using a wavelength of at least about 100 nm, for example, 193 nm, a wafer stage of identifying the location by using an encoder, an optical system with lenses, and a straight slit, and may use a transmissive photomask. In contrast, the EUV device may include an EUV scanner using a wavelength of about 20 nm or less, for example, 13.5 nm, a wafer stage of identifying the location by using an interferometer, an optical system with mirrors, and a curved slit, and may use a reflective photomask. Because of such differences between the DUV device and the EUV device, it is impossible to correct the K20 component that originates from the mirror of the optical system of the EUV device.

In the environment in which the DUV device and the EUV device are used together, the K20 component may be removed or minimized during the exposure process in the DUV device, and thus, the K20 component may be minimized during the exposure process in the EUV device later.

In an embodiment of the inventive concept, the K7 component having a correlation with the K20 component may be used in the second exposure apparatus to minimize or remove the K20 component. As described above, the K20 component has a crosstalk relationship with the K7 component. In particular, the K20 component is a parasitic component generated according to a change in the K7 component. The K7 component changes as the reticle stage is tilted in the scan direction. For example, when a reticle y-axis tilt (image tilt Ry) occurs, K6 (e.g., rotation about the y-axis), K7, and K20 may change together. In another example, the K7 control may cause K6 and K20 fluctuations. Because the K20 component changes according to the change in the K7 component, a variation value of the K7 component, which corresponds to the K20 component required to be corrected, may be calculated based on the crosstalk ratio between the K2 component and the K7 component, and by adjusting the reticle stage to change the K7 component by the amount equal to the variation value, the K20 component, which cannot be corrected through physical actuation, may be corrected, according to embodiments of the present disclosure.

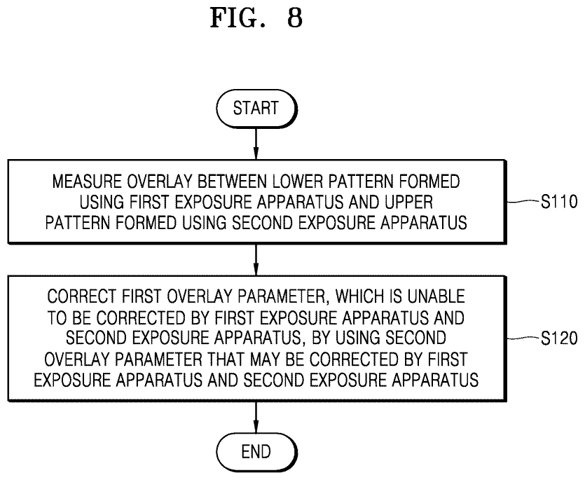

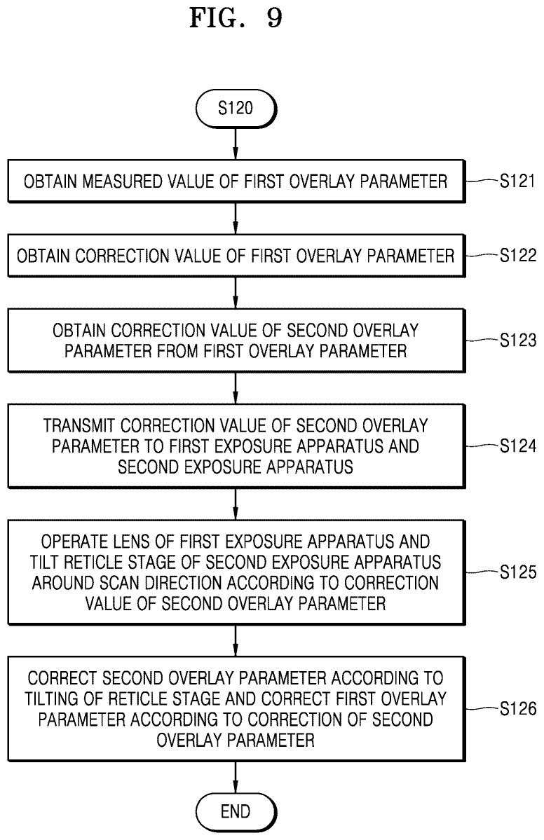

FIG. 8 is a schematic flowchart of an overlay correction method according to embodiments, and FIG. 9 is a schematic flowchart of an example of an operation of correcting a first overlay parameter using a second overlay parameter of FIG. 8. The flowcharts are described with reference to FIGS. 1 to 5 collectively, and the descriptions already provided in the descriptions of FIGS. 1 to 5 are briefly repeated or omitted.

Referring to FIG. 8, the overlay correction method according to one or more embodiments of the inventive concept includes operation S110 of measuring an overlay between a lower pattern and an upper pattern on a wafer.

The lower pattern and the upper pattern may be stacked on the wafer W. The lower pattern may be formed using the first exposure apparatus 100, and the upper pattern may be formed using the second exposure apparatus 200 operating with an exposure method different from that of the first exposure apparatus 100. As described above, the first exposure apparatus 100 may be a DUV device using a light source with a wavelength ranging from about 150 nm to about 500 nm, and the second exposure apparatus 200 may be an EUV device using a light source with a wavelength ranging from 5 nm to about 50 nm.

The overlay between the lower pattern and the upper pattern may be measured by the measuring device 180. The measuring device 180 may measure a first overlay parameter and a second overlay parameter among the overlay parameters (e.g., exposure parameters). The first overlay parameter may be a component in which an overlay error increases three-dimensionally (e.g., as a cube or third power) in a scan direction as the first overlay parameter moves farther from the center towards both sides in a second direction that is perpendicular to the first direction (e.g., the scan direction), and the second overlay parameter may be a component in which an overlay error increases two-dimensionally (e.g., as a square or second power) as the second overlay parameter moves farther from the center towards both sides in a second direction that is perpendicular to the first direction (e.g., the scan direction). The first overlay parameter may be a K20 component, while the second overlay parameter may be a K7 component. For example, K7 may indicate a second order distortion in x, while K20 may indicate a third order distortion in y.

Next, in operation S120, the first overlay parameter may be corrected using the second overlay parameter. Additional details of operation S120 are given in the example of FIG. 9. For example, among the overlay components, the first overlay parameter, which is unable to be corrected through the physical actuation of the first exposure apparatus and the second exposure apparatus, may be corrected by using the second overlay parameter, which has a crosstalk relationship with the first overlay parameter and may be corrected through the physical actuation of the first exposure apparatus and the second exposure apparatus. K7 and K20 may be affected by mutual crosstalk. For example, when a reticle y-axis tilt (image tilt Ry) occurs, K7 and K20 may change together. In another example, the K7 control may cause K20 fluctuations.

The first overlay parameter is a parasitic parameter generated according to the change in the second overlay parameter. The first overlay parameter has a crosstalk relationship with the second overlay parameter, and the first overlay parameter may vary according to the change in the second overlay parameter multiplied by the amount of the crosstalk ratio. The crosstalk ratio between the first overlay parameter and the second overlay parameter may vary depending on exposure apparatuses.

The first overlay parameter, which is the K20 component, may not be corrected through the physical actuation of the DUV device and the EUV device, but the second overlay parameter, which is the K7 component, may be corrected through the physical actuation of the DUV device and the EUV device. As described above, the K7 component may change because of the actuation of a lens or mirror included in an optical system of the first exposure apparatus that is the DUV device, and may also change as the reticle stage is tilted relative to the scan direction of the reticle stage of the second exposure apparatus that is the EUV device. In the second exposure apparatus, the K20 component, which has the crosstalk relationship with the K7 component, may be corrected by the amount of the crosstalk ratio, according to the change of the K7 component.

Referring to FIG. 9, operation S120 of correcting the first overlay parameter may include operation S121 of obtaining a measured value of the first overlay parameter. For example, the first overlay parameter may be measured by the measuring device 180, and the measured value of the first overlay parameter that is measured by the measuring device 180 may be transmitted to the data obtaining unit 430 of the main alignment controller 400.

Next, in operation S122, the correction value of the first overlay parameter may be obtained. The measured value of the first overlay parameter may be transmitted from the data obtaining unit 430 to the alignment controller 410. The alignment controller 410 may calculate the correction value of the first overlay parameter based on the transmitted measured value of the first overlay parameter. For example, the alignment controller 410 may calculate the correction value of the first overlay parameter based on a difference between the measured value of the first overlay parameter and an error-free reference value of the first overlay parameter.

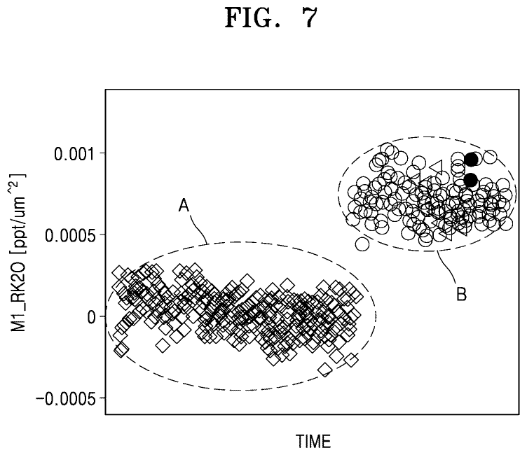

FIG. 7 is a graph showing measurement results of an overlay between an upper pattern and a lower pattern. FIG. 7 is a graph showing RK20 components of the lower pattern and the upper pattern, which are formed using both the DUV device and the EUV device, over time. Referring to FIG. 7, the measurement result for region A shows that the RK20 component was obtained near 0 ppt/μm². It indicates that the overlay error of the RK20 component between the lower pattern and the upper pattern is close to 0. However, the measurement result for region B indicates that the RK20 component was measured in the range from about 0.0005 ppt/μm² to about 0.001 ppt/μm², and accordingly the overlay error of the RK20 component has occurred. In other words, the RK20 component needs to be corrected so that the measurement result for region B is near 0 ppt/μm², similar to the measurement result for region A.

The alignment controller 410 may set the difference between the measured value of the first overlay parameter (the RK20 component) and the error-free reference value of the first overlay parameter as the correction value of the first overlay parameter.

Next, in operation S123, the correction value of the second overlay parameter may be obtained. The alignment controller 410 may calculate the correction value of the second overlay parameter, based on the correction value of the first overlay parameter. For example, the alignment controller 410 may use the crosstalk relationship between the first overlay parameter and the second overlay parameter. As described above, K20 that is the first overlay parameter may be a parasitic parameter of K7 that is the second overlay parameter, and the first overlay parameter and the second overlay parameter may have a crosstalk ratio. The alignment controller 410 may multiply the correction value of the first overlay parameter (e.g., a correction value of K20) by the crosstalk ratio between the first overlay parameter and the second overlay parameter and may thereby calculate the correction value of the second overlay parameter (e.g., a correction value of K7).

Note that the disclosed system and methods can correct the first overlay parameter (e.g., K20) indirectly by determining a corresponding correction value to the second overlay parameter (e.g., K7) in operation S123, and performing actuation to correct the second overlay parameter. However, during earlier operation S121, it is the value of the first parameter (e.g., K20) that is directly measured, and in operation S122, the correction value of the first parameter is directly determined based on the measurement of the first parameter. Therefore, in operation S123, the correction value of the second overlay parameter is calculated so as to correspond to the already-determined correction value of the first overlay parameter (e.g., based on the correction value of the first overlay parameter multiplied by the crosstalk ratio). Then, the second overlay parameter can be corrected by this amount, which will also indirectly cause the first overlay parameter to be corrected by its respective correction value.

Then, in operation S124, the correction value of the second overlay parameter may be transmitted to the first exposure apparatus and the second exposure apparatus. The correction value of the second overlay parameter calculated by the alignment controller 410 may be transmitted to the first exposure apparatus 100 and the second exposure apparatus 200 by the feedback unit 420.

Next, in operation S125, the second overlay parameter may be corrected in the first exposure apparatus by operating the lens or mirror in the optical system of the first exposure apparatus according to the transmitted correction value of the second overlay parameter, and the second overlay parameter may also be corrected in the second exposure apparatus by tilting the reticle stage of the second exposure apparatus around the scan direction of the reticle stage. The first data obtaining unit 168 of the first exposure apparatus 100 and the second data obtaining unit 268 of the second exposure apparatus 200 may receive the correction value of the second overlay parameter from the feedback unit 420 of the main alignment controller 400. The first data obtaining unit 168 and the second data obtaining unit 268 may transmit feedback on the correction value of the second overlay parameter to the first main controller 166 and the second reticle stage controller 262, respectively.

The first main controller 166 may control the lens or mirror in the first optical system 130 or the second optical system 170, based on the correction value of the second overlay parameter. In addition, the second reticle stage controller 262 may control the tilting of the second reticle stage 240 around the scan direction D1 of the second reticle stage 240, based on the correction value of the second overlay parameter. Because the first exposure apparatus 100 and the second exposure apparatus 200 perform the exposure process according to the same correction value of the second overlay parameter, the second overlay parameter can be corrected, according to embodiments of the disclosed system and methods. For example, no error may occur subsequently in the second overlay parameter.

In operation S126, the second overlay parameter may be corrected based on the operation of the first optical system and the second optical system and the tilting of the second reticle stage, and the first overlay parameter may be corrected by an amount equal to the crosstalk ratio multiplied by the correction of the second overlay parameter. As described above, because the first overlay parameter is a parasitic parameter of the second overlay parameter and varies according to the change in the second overlay parameter, the first overlay parameter may be corrected by an amount equal to the correction value of the second overlay parameter multiplied by the crosstalk ratio between the first overlay parameter and the second overlay parameter. Therefore, the first overlay parameter (the K20 parameter), which is unable to be corrected through physical actuation, is corrected using the second overlay parameter (the K7 parameter), thus reducing the overlay deterioration caused by the K20 parameter.

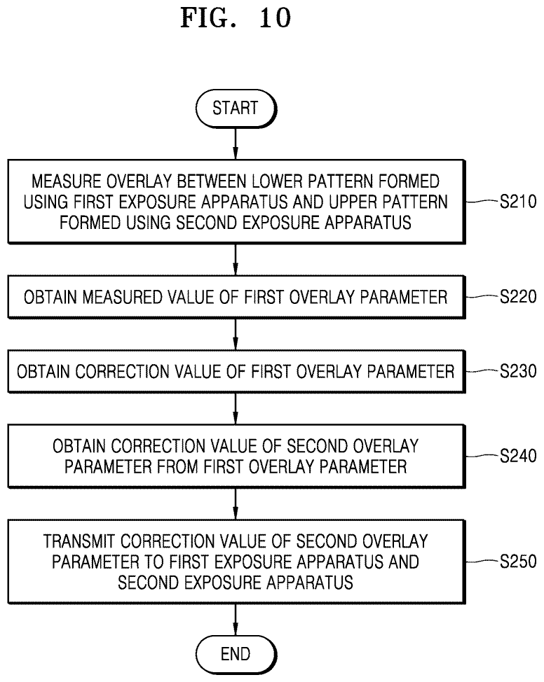

FIG. 10 is a schematic flowchart of an overlay correction method according to other embodiments. The flowchart is described with reference to FIGS. 8 and 9 collectively, and the descriptions already provided with reference to FIGS. 8 and 9 are briefly repeated or omitted. For example, FIG. 10 shows additional details of applying the overlay correction method using the first exposure apparatus and the second exposure apparatus, for example within the context of manufacturing a semiconductor device.

Referring to FIG. 10, the overlay correction method according to another embodiment of the inventive concept may include operation S210 of measuring an overlay between a lower pattern formed using the first exposure apparatus and an upper pattern formed using the second exposure apparatus, operation S220 of obtaining a measured value of a first overlay parameter among overlay parameters of the overlay, operation S230 of obtaining a correction value of the first overlay parameter, operation S240 of obtaining a correction value of the second overlay parameter from the correction value of the first overlay parameter, and operation S250 of transmitting the correction value of the second overlay parameter to the first exposure apparatus and the second exposure apparatus. Here, the first overlay parameter may be a K20 parameter, the second overlay parameter may be a K7 parameter, and each operation is the same as that described above in the description of FIG. 9.

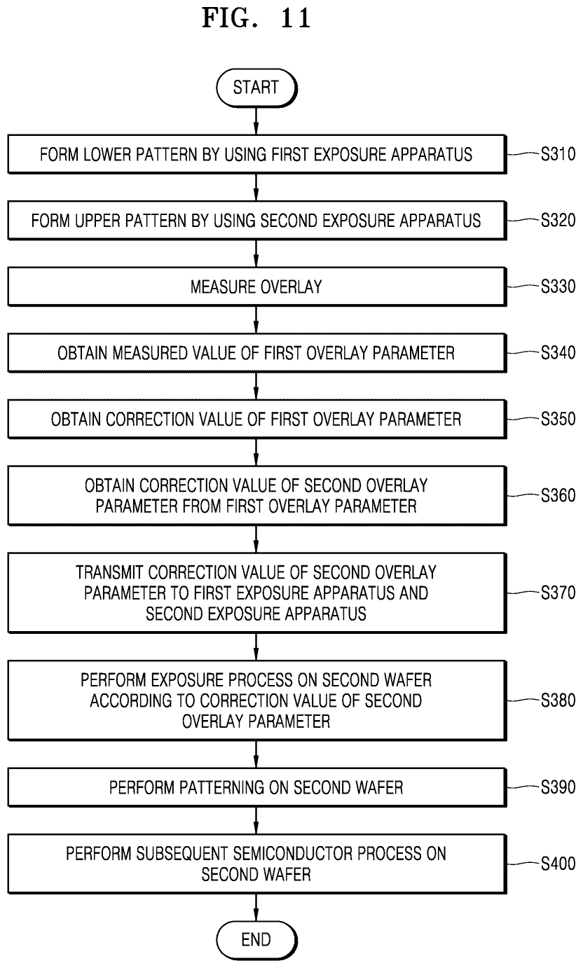

FIG. 11 is a schematic flowchart of a method of manufacturing a semiconductor device, according to embodiments. The flowchart is described with reference to FIGS. 8 to 10 together, and the descriptions already provided in the description of FIGS. 8 to 10 are briefly repeated or omitted.

Referring to FIG. 11, the method of manufacturing a semiconductor device may sequentially include operation S310 of forming a lower pattern on a first semiconductor substrate by using a first exposure apparatus, operation S320 of forming an upper pattern on the lower pattern by using a second exposure apparatus, operation S330 of measuring an overlay between the lower pattern and the upper pattern, operation S340 of obtaining a measured value of a first overlay parameter among overlay parameters of the overlay, operation S350 of obtaining a correction value of the first overlay parameter, operation S360 of obtaining a correction value of a second overlay parameter, which has a crosstalk relationship with the first overlay parameter, based on the correction value of the first overlay parameter, and operation S370 of transmitting the correction value of the second overlay parameter to the first exposure apparatus and the second exposure apparatus. Here, the first semiconductor substrate may be a first wafer, the first overlay parameter may be a K20 parameter, the second overlay parameter may be a K7 parameter, and each operation may be the same as that provided above in the description of FIG. 9.

Then, in operation S380, the first exposure apparatus and the second exposure apparatus may perform the exposure process on a second semiconductor substrate according to the correction value of the second overlay parameter. The second semiconductor substrate is a second wafer. The exposure process on the second wafer refers to a process in which light is incident to a reticle and the light passing through the reticle or reflected therefrom is projected onto the second wafer through an optical system. Here, the light may be projected onto photoresist (PR) on the second wafer. In addition, the exposure process on the second wafer may include forming a PR pattern by performing a developing process and a cleaning process on the PR.

Operation S380 of performing the exposure process on the second semiconductor substrate may include steps substantially similar to operation S125 of tilting the reticle stage around the scan direction and operation S126 of correcting the first overlay parameter through the correction of the second overlay parameter, as described in the example of FIG. 9. However, in this example, operation S380 is described in terms of the wafer, so as to highlight the connection with subsequent operations. Accordingly, operation S380 of performing the exposure process on the wafer may include an operation of correcting the first overlay parameter through the correction of the second overlay parameter.

After operation S380 of performing the exposure process on the second semiconductor substrate, patterning is performed on the second semiconductor substrate in operation S390. The patterning on the second semiconductor substrate may refer to a process of forming a pattern on the second semiconductor substrate through an etching process by using a PR pattern as a mask. The pattern on the second semiconductor substrate may be ultimately considered as the result of transferring a transmissive layer pattern of the first reticle R1 or an absorption layer pattern of the second reticle R2 onto the second semiconductor substrate through the exposure process and the etching process.

Then, in operation S400, a subsequent semiconductor process on the second semiconductor substrate is performed. The subsequent semiconductor process may include various processes. For example, the subsequent semiconductor process may include a deposition process, an etching process, an ion process, a cleaning process, and the like. In addition, the subsequent semiconductor process may include a singulation process of separating the wafer into individual semiconductor chips, a test process of testing the semiconductor chips, and a packaging process of packaging the semiconductor chips. Through the subsequent semiconductor process on the second semiconductor substrate, the semiconductor device may be completed.

While the inventive concept has been particularly shown and described with reference to embodiments thereof, it will be understood that various changes in form and details may be made therein without departing from the spirit and scope of the following claims.

1. A semiconductor manufacturing method with overlay correction, comprising:
measuring an overlay between a lower pattern and an upper pattern, wherein the lower pattern is formed using a first exposure apparatus and the upper pattern is formed using a second exposure apparatus operating with an exposure method that is different from an exposure method of the first exposure apparatus;
correcting, among components of the overlay, a first overlay parameter by correcting a second overlay parameter that has a crosstalk relationship with the first overlay parameter, the second overlay parameter being corrected via physical actuation of the first exposure apparatus and the second exposure apparatus; and
using the corrected first overlay parameter to manufacture a semiconductor device.

2. The method of claim 1, wherein the first exposure apparatus uses a light source with a wavelength ranging from about 150 nm to about 500 nm, and the second exposure apparatus uses a second light source with a wavelength ranging from about 5 nm to about 50 nm.

3. The method of claim 1, wherein the first overlay parameter has a first overlay error that increases as a third power in a scan direction as the first overlay parameter moves farther from a center towards both sides in a second direction that is perpendicular to a first direction, the first direction being the same as the scan direction in an exposure process, and
the second overlay parameter has a second overlay error that increases as a second power as the second overlay parameter moves farther from the center towards both sides in the second direction that is perpendicular to the first direction.

4. The method of claim 1, wherein the first overlay parameter comprises a parasitic parameter generated according to a change in the second overlay parameter.

5. The method of claim 1, wherein the correcting of the first overlay parameter comprises:
obtaining a measured value of the first overlay parameter;
obtaining a first correction value of the first overlay parameter,
obtaining a second correction value of the second overlay parameter from the first correction value of the first overlay parameter;
transmitting the second correction value of the second overlay parameter to the first exposure apparatus and the second exposure apparatus; and
correcting the second overlay parameter by operating a lens or a mirror of the first exposure apparatus according to the transmitted second correction value of the second overlay parameter or by tilting a reticle stage of the second exposure apparatus around a scan direction of the reticle stage,
wherein the correcting the second overlay parameter according to the operation of the lens or the mirror and the tilting of the reticle stage causes the correcting of the first overlay parameter by an amount of a crosstalk ratio in the correction of the second overlay parameter.

6. The method of claim 5, wherein the obtaining of the first correction value of the first overlay parameter comprises calculating the first correction value of the first overlay parameter, based on a difference between an error-free reference value of the first overlay parameter and the measured value of the first overlay parameter.

7. The method of claim 5, wherein the obtaining of the second correction value of the second overlay parameter comprises multiplying the crosstalk ratio between the first overlay parameter and the second overlay parameter by the first correction value of the first overlay parameter.

8. The method of claim 1, wherein the first overlay parameter cannot be corrected via the physical actuation of the first exposure apparatus and the second exposure apparatus without correcting another overlay parameter among the components of the overlay.

9. A semiconductor manufacturing method with overlay correction, comprising:
measuring an overlay between a lower pattern formed using a first exposure apparatus and an upper pattern formed using a second exposure apparatus;
obtaining a measured value of a first overlay parameter among overlay parameters of the overlay;
obtaining a first correction value of the first overlay parameter;
obtaining a second correction value of a second overlay parameter from the first correction value of the first overlay parameter;
transmitting the second correction value of the second overlay parameter to the first exposure apparatus and the second exposure apparatus,
wherein an exposure method of the first exposure apparatus is different from an exposure method of the second exposure apparatus, and
wherein the first overlay parameter has a crosstalk relationship with the second overlay parameter; and
using the second correction value of the second overlay parameter to manufacture a semiconductor device.

10. The method of claim 9, wherein:
the first exposure apparatus uses a light source with a wavelength ranging from about 150 nm to about 500 nm, and the second exposure apparatus uses a second light source with a wavelength ranging from about 5 nm to about 50 nm.

11. The method of claim 9, wherein the first overlay parameter has a first overlay error that increases as a third power in a scan direction as the first overlay parameter moves farther from a center towards both sides in a second direction that is perpendicular to a first direction, the first direction being the same as the scan direction in an exposure process, and
the second overlay parameter has a second overlay error that increases as a second power as the second overlay parameter moves farther from the center towards both sides in the second direction that is perpendicular to the first direction.

12. The method of claim 9, wherein the first overlay parameter comprises a parasitic parameter generated according to a change in the second overlay parameter.

13. The method of claim 9, wherein the second overlay parameter varies by operating a lens or a mirror of the first exposure apparatus and by tilting a reticle stage of the second exposure apparatus around a scan direction of the reticle stage.

14. The method of claim 9, wherein the obtaining of the first correction value of the first overlay parameter comprises calculating the first correction value of the first overlay parameter, based on a difference between an error-free reference value of the first overlay parameter and the measured value of the first overlay parameter.

15. The method of claim 9, wherein the obtaining of the second correction value of the second overlay parameter comprises multiplying a crosstalk ratio between the first overlay parameter and the second overlay parameter by the first correction value of the first overlay parameter.

16. The method of claim 9, wherein:
the second overlay parameter is corrected as the first exposure apparatus operates a lens or a mirror of the first exposure apparatus according to the transmitted second correction value of the second overlay parameter, or
the second overlay parameter is corrected as the second exposure apparatus tilts a reticle stage of the second exposure apparatus around a scan direction of the reticle stage according to the second correction value of the second overlay parameter.

17. (canceled)

18. A method of manufacturing a semiconductor device by using a first exposure apparatus and a second exposure apparatus which use different exposure methods, the method comprising:
forming a lower pattern on a first semiconductor substrate by using the first exposure apparatus;
forming an upper pattern on the lower pattern by using the second exposure apparatus;
measuring an overlay between the lower pattern and the upper pattern;
obtaining a measured value of a first overlay parameter among overlay parameters of the overlay;
obtaining a first correction value of the first overlay parameter;
obtaining a second correction value of a second overlay parameter having a crosstalk relationship with the first overlay parameter, from the first correction value of the first overlay parameter;
transmitting the second correction value of the second overlay parameter to the first exposure apparatus and the second exposure apparatus;
performing an exposure process on a second semiconductor substrate by using the first exposure apparatus and the second exposure apparatus according to the transmitted second correction value of the second overlay parameter;
performing patterning on the second semiconductor substrate; and
performing a subsequent semiconductor process on the second semiconductor substrate,
wherein, in the performing of the exposure process, the second overlay parameter is corrected by operating a lens of the first exposure apparatus according to the transmitted second correction value of the second overlay parameter, the second overlay parameter is corrected by tilting a reticle stage of the second exposure apparatus around a scan direction of the reticle stage according to the transmitted second correction value of the second overlay parameter, and the first overlay parameter is corrected by an amount depending on a crosstalk ratio in the second correction value of the second overlay parameter in the second exposure apparatus.

19. The method of claim 18, wherein the first overlay parameter has a first overlay error that increases as a third power in the scan direction as the first overlay parameter moves farther from a center towards both sides in a second direction that is perpendicular to a first direction, the first direction being the same as the scan direction in the exposure process, and
the second overlay parameter has a second overlay error that increases as a second power as the second overlay parameter moves farther from the center towards both sides in the second direction that is perpendicular to the first direction.

20. The method of claim 18, wherein the obtaining of the first correction value of the first overlay parameter comprises calculating the first correction value of the first overlay parameter, based on a difference between an error-free reference value of the first overlay parameter and the measured value of the first overlay parameter.

21. The method of claim 18, wherein the obtaining of the second correction value of the second overlay parameter comprises multiplying the crosstalk ratio between the first overlay parameter and the second overlay parameter by the first correction value of the first overlay parameter.
